(19) United States
(12) Patent Application Publication
(10) Pub. No.: US 2009/0072895 A1
(43) Pub. Date: Mar. 19, 2009

(54) SIGNAL PROCESSING WITH INTERFERENCE COMPENSATION

(75) Inventors: Willebrordus Gerardus Traa, Leende (NL); Jan Hendrik Haanstra, Nijmegen (NL); Edwin Schapendonk, Oss (NL)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 11/917,086

(22) PCT Filed: May 30, 2006
(86) PCT No.: PCT/IB2006/051720

§ 371 Date: Sep. 22, 2008

(30) Foreign Application Priority Data
Jun. 14, 2005 (EP) 05105205.8

(51) Int. Cl. H03K 5/00

(52) U.S. Cl. 327/551

(57) ABSTRACT

A processor reduces periodic interference signal components in an input signal to obtain a desired signal. The desired signal has a predefined characteristic during an interval of time. First, an interference-representing signal (S1-S13) is stored (SWM1, C1-C13) on the basis of the input signal that occurs within the interval of time during which the desired signal has the predefined characteristic. The interference-representing signal (S1-S13) represents at least one period of a periodic interfering signal. Then, on the basis of the interference-representing signal (S1-S 13), compensation (ICS) is repetitively provided (SWM2, SUB) for the periodic interfering signal.

### FIELD OF THE INVENTION

An aspect of the invention relates to a signal processing arrangement that comprises an interference compensator. The signal processing arrangement may be, for example, a video processor that processes a video input signal, which is to be displayed. Other aspects of the invention relate to a method of processing a signal, a computer program product for a signal processing arrangement, and an information-rendering system.

### DESCRIPTION OF PRIOR ART

U.S. Pat. No. 6,310,570 describes an analog-to-digital converter that operates in the presence of clock noise interference. The analog-to-digital converter is configured with sampling clock phase selection circuitry. This enables operation of the analog-to-digital converter at appropriate sampling time intervals with respect to the interfering noise. The selection circuitry selects the appropriate clock phase among a plurality of sampling clock phases.

U.S. Pat. No. 4,768,094 describes a noise suppressing circuit in which the noise in a video signal is detected only during the blanking period.

US patent application 2005/0096002 describes a method and device for suppressing periodic interference signals, including a unit to provide a period length for the periodic interference signal, an interference detection unit for detecting a signal corresponding to the interference signal, and a subtraction unit for subtracting the signal corresponding to the interference signal. The interference detection unit carries out multiple superpositioning of the input signal and scales the multiple superpositioned input signal depending on the period length of the interference signal in order to detect the signal corresponding to the interference signal. A signal which corresponds to the interference signal should be determined in a pause in speech. This has the advantage that in order to determine the signal corresponding to the interference signal it is possible to average over a comparatively small number of period lengths, since the useful data component is absent in a pause in speech.

### SUMMARY OF THE INVENTION

It is an object of the invention to provide for a less complex way to reduce periodic interference signal components. The invention is defined by the independent claims. The dependent claims define advantageous embodiments.

According to an aspect of the invention, a processor processes an input signal that comprises a desired signal. The desired signal has a predefined characteristic during an interval of time. An interference compensator stores an interference-representing signal on the basis of the input signal that occurs within the interval of time during which the desired signal has the predefined characteristic. The interference-representing signal represents at least one period of a periodic interfering signal. The interference compensator repetitively provides, on the basis of the interference-representing signal, compensation for the periodic interfering signal.

The invention takes the following aspects into consideration. In many signal processing applications, an input signal comprises not only a desired signal but also one or more interfering signals. This is particularly true for signal processing applications in which various different circuits, which carry out various different processes, are relatively close to each other because these circuits forms part of an integrated circuit or a micro module. A crosstalk of a signal from one circuit to another circuit may cause an interfering signal within that other circuit. Such a crosstalk is difficult to avoid when the circuits are relatively close to each other. Moreover, it may be difficult, or even impossible, to distinguish an interfering signal from a desired signal by means of, for example, filtering.

An interfering signal may have a periodic nature. For example, the interfering signal may be due to a crosstalk of a clock signal from one circuit to another circuit, which may have a different clock signal. Clock signal synchronization may alleviate interference problems. Respective clock signals for respective circuits have an identical frequency or are an exact integer multiple of a basic clock frequency. An appropriate setting of the respective phases of the respective clock signals can avoid that an interfering signal, which is due to a clock-signal crosstalk, affects processing of a desired signal. The aforementioned prior art appears to take this approach.

However, signal synchronization between various different circuits may adversely affect signal processing or may even not be possible. For example, a conventional analog video signal, which has a line frequency, is preferably processed in synchronization with the line frequency. The line frequency may differ from one to another video signal. In contradistinction, an audio component, which forms part a video signal, is preferably processed by a digital audio processor that receives a fixed-frequency clock signal from a crystal oscillator. Similarly, a controller, which controls video and audio processing, also preferably receives a fixed-frequency clock signal. Consequently, the prior-art approach is ill suited for a signal processing application that combines video processing, audio processing and control functions on a single integrated circuit or a micro module.

In accordance with the aforementioned aspect of the invention, an interference-representing signal is established on the basis of an input signal that occurs within an interval of time during which a desired signal, which forms part of the input signal, has a predefined characteristic. The interference-representing signal represents at least one period of a periodic interfering signal. On the basis of the interference-representing signal, compensation is provided for the periodic interfering signal.

The invention does not require precise signal synchronization. It is sufficient that a desired signal has a predefined characteristic during an interval of time. An interfering signal can be distinguished from the desired signal during that interval of time thanks to a priori knowledge of the desired signal. Knowledge of the interfering signal is gained. Since the interfering signal has a periodic nature, this knowledge can be used to predict, as it were, a continuation of the interfering signal outside the interval of time during which the desired signal has the predefined characteristic. As a result, the knowledge of the interfering signal, which is gained within the time interval during which the desired signal has the predefined characteristic, can be used to effectively compensate for the interfering signal outside that time interval. Since the invention does not require precise signal synchronization, the invention allows interference suppression in a great variety of applications.

Another advantage of the invention relates to the following aspects. It has been explained hereinbefore that the invention allows interference compensation without this requiring precise signal synchronization. As a result, the invention allows integration of a great variety of various different circuits, which carry out various different processes, on a single semiconductor chip or in a single micro module. Such circuit integration generally reduces costs. For example, a video processor, an audio processor, and a controller, if necessary, can be implemented on a single semiconductor chip with each of these processors providing high-quality signal processing. Consequently, the invention allows cost reduction.

These and other aspects of the invention will be described in greater detail hereinafter with reference to drawings.

### BRIEF DESCRIPTION OF THE DRAWINGS

FIG. 1 is a block diagram that illustrates a video display system,

FIG. 2 is a block diagram that illustrates a video processor, which forms part of the video display system,

FIG. 3 is a block diagram that illustrates an interference compensation circuit, which forms part of the video processor,

FIG. 4 is a time diagram that illustrates operations that the interference compensation circuit carries out.

### DETAILED DESCRIPTION

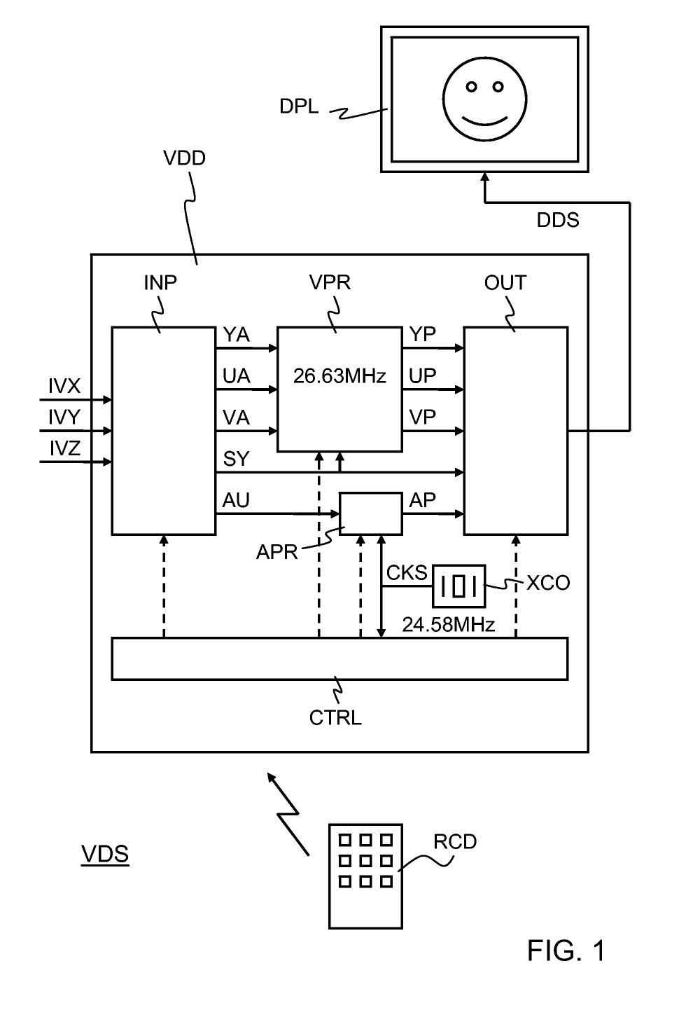

FIG. 1 illustrates a video display set VDS. The video display set VDS comprises a video display driver VDD, a display device DPL, and a remote control device RCD. The video display driver VDD comprises an input circuit INP, a video processor VPR, an audio processor APR, an output circuit OUT, a crystal oscillator XCO, and a controller CTRL. The video display driver VDD receives various input video signals IVX, IVY, IVZ from various video sources, which are not shown. The display device DPL may be, for example, a flat panel display of the liquid crystal type.

The video display driver VDD globally operates as follows. Let it be assumed that a user selects a particular video source on his or her remote control device RCD. The remote control device RCD sends a command to the controller CTRL that indicates the particular video source to be selected. In response, the controller CTRL causes the input circuit INP to select that particular video source.

The input circuit INP derives a set of signals from the input video signal of the video source that the user has selected. The set of signals comprises an analog luminance signal YA, an analog first chrominance signal UA, and an analog second chrominance signal VA. These signals represent video information and will collectively be referred to as analog video signals YA, UA, VA hereinafter. The set of signals further comprises a synchronization signal SY and an audio signal AU. The synchronization signal SY may comprise various components, such as, for example, a horizontal synchronization component and a vertical synchronization component.

The video processor VPR converts the analog video signals YA, UA, VA into digital video signals, which have a sample frequency of, for example, 26.63 MHz. Subsequently, the video processor VPR processes these digital video signals so as to enhance various display characteristics, such as, for example, sharpness, brightness, and contrast. The video processor VPR may also provide various video features, such as, for example, double window and panorama view. The user may adjust one or more display characteristics and select a video feature by means of his or her remote control device RCD. The video processor VPR applies processed video signals YP, UP, VP to the output circuit OUT. The audio processor APR processes the audio signal AU, which the input circuit INP provides, so as to obtain a processed audio signal AP, which the output circuit OUT receives.

The output circuit OUT provides a display driver signal DDS in response to the processed video signals YP, UP, VP, the synchronization signal SY, and the processed audio signal AP. To that end, the output circuit OUT may carry out various signal processing operations, such as, for example, amplification, level shifting, bias voltage generation, and synchronization. The display device DPL, which receives the display driver signal DDS, displays the input video signal that the user has selected. The display device DPL may furthermore produce a sound, which is comprised in the input video signal.

The crystal oscillator XCO generates a system clock signal CKS, which has a frequency of 24.58 MHz. The audio processor APR and the controller CTRL receive the system clock signal CKS. The system clock signal CKS defines discrete instants when switching elements that form part of the audio processor APR or the controller CTRL may change state.

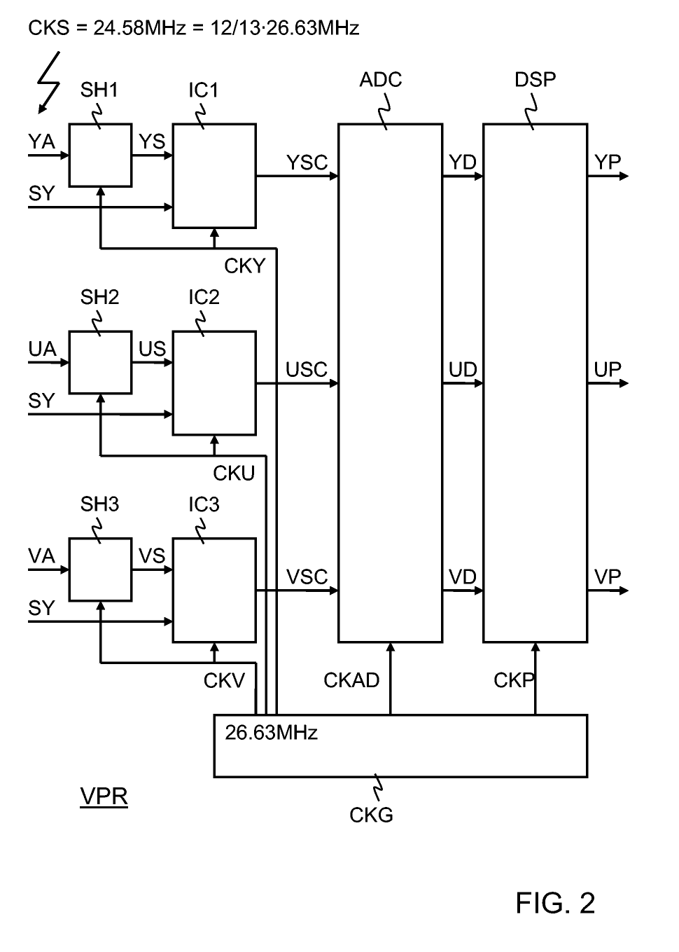

FIG. 2 illustrates the video processor VPR. The video processor VPR comprises three sample-and-hold circuits SH1, SH2, SH3, one for each of the analog video signals YA, UA, VA, respectively, and three interference compensation circuits IC1, IC2, IC3, one for each of the analog video signals YA, UA, VA, respectively. The video processor VPR further comprises an analog-to-digital converter ADC, a digital signal processor DSP, and a clock generator CKG.

The video processor VPR operates as follows. Sample-and-hold circuit SH1 samples the analog luminance signal YA. A luminance sample clock signal CKY, which has a frequency of 26.63 MHz, defines respective instants when sample-and-hold circuit SH1 takes samples from the analog luminance signal YA. Sample-and-hold circuit SH1 provides a stream of analog luminance samples YS, which has a rate that is equal to the luminance sample clock signal CKY.

Sample-and-hold circuits SH2, SH3 sample the analog first chrominance signal UA and the analog second chrominance signal VA, respectively, in a similar fashion. A first chrominance sample clock signal CKU and a second chrominance sample clock signal CKV define respective sampling operations of sample-and-hold circuits SH2, SH3, respectively. These chrominance sample clock signals CKU, CKV may have the same frequency as the luminance sample clock signal CKY, which is 26.63 MHz, or a different frequency. The three respective sample clock signals CKY, CKU, CKV, may each have a different phase. Sample-and-hold circuit SH2 provides a stream of analog first chrominance samples US. Sample-and-hold circuit SH3 provides a stream of analog second chrominance samples VS.

FIG. 2 illustrates that the analog luminance signal YA, which sample-and-hold circuit SH1 receives, may comprise a parasitic component that is due to a crosstalk of the system clock signal CKS. Sample-and-hold circuit SH1 will sample this parasitic component. This will produce a folding component in the stream of analog luminance samples YS. The folding component has a frequency of 2.05 MHz, which is the difference between the frequency of the system clock signal CKS, which is 24.58 MHz, and the frequency of the luminance sample clock signal CKY, which is 26.63 MHz. Similarly, a crosstalk of the system clock signal CKS may produce a 2.05 MHz folding component in the stream of analog first chrominance samples US and in the stream of analog second chrominance samples VS. Interference compensation circuit IC1 suppresses the folding component, which is due to a crosstalk of the system clock signal CKS. Interference compensation circuit IC1 achieves this suppression on the basis of the synchronization signal SY, the luminance clock signal CKY, and the stream of analog luminance samples YS itself. This will be explained in greater detail hereinafter.

Interference compensation circuit IC1 applies an interference-compensated stream of analog luminance samples YSC to the analog-to-digital converter ADC. The interference-compensated stream YSC is similar to the stream of analog luminance samples YS but substantially without the folding component, which has been compensated for. Similarly, interference compensation circuit IC2 provides an interference-compensated stream of analog first chrominance samples USC. Interference compensation circuit IC3 provides an interference-compensated stream of analog second chrominance samples VSC.

The analog-to-digital converter ADC converts the interference-compensated stream of analog luminance samples YSC into a digital luminance signal YD. The digital luminance signal YD is a stream of digital luminance samples in the form of binary values. The analog-to-digital converter ADC establishes a binary value for each sample in the interference-compensated stream of analog luminance samples YSC. The binary value reflects the amplitude of the sample concerned. Similarly, the analog-to-digital converter ADC converts the interference-compensated stream of analog first chrominance samples into a digital first chrominance signal UD. The analog-to-digital converter ADC converts the interference-compensated stream of analog second chrominance samples into a digital second chrominance signal VD.

The analog-to-digital converter ADC may comprise a single analog-to-digital conversion circuit, which operates in a time-multiplexed mode. In a conversion cycle, the analog-to-digital conversion circuit first establishes a binary value for an analog luminance sample. Subsequently, the analog-to-digital conversion circuit establishes a binary value for an analog first chrominance sample. Subsequently, the analog-to-digital conversion circuit establishes a binary value for an analog second chrominance sample. This completes the conversion cycle, which is followed by a new, similar conversion cycle.

Such a time multiplexed operation requires an analog-to-digital clock signal CKAD having a frequency that is three times the frequency of the respective sample clock signals. For example, the frequency of analog-to-digital clock signal CKAD may be 79.89 MHz, which is three times 26.63 MHz. The analog-to-digital conversion circuit establishes a binary value for a sample within each period of the analog-to-digital clock signal CKAD. A conversion cycle comprises three periods of the analog-to-digital clock signal CKAD, which corresponds to one period of the respective sample clock signals CKY, CKU, CKV.

The digital signal processor DSP processes the digital luminance signal YD, the digital first chrominance signal UD, and the digital second chrominance signal VD that the analog-to-digital converter ADC provides. This processing allows enhancement of various display characteristics, such as, for example, sharpness, brightness, and contrast, as mentioned hereinbefore. The digital signal processor DSP provides the processed video signals YP, UP, VP, which are also illustrated in FIG. 1. The digital signal processor DSP receives a processing clock signal CKP, which may have a frequency that is equal to the frequency of the respective sample clock signals CKY, CKU, CKV. That is, the frequency of the processing clock signal CKP may be 26.63 MHz.

The clock generator CKG may synchronize the respective sample clock signals, the analog-to-digital clock signal CKAD, and the processing clock signal CKP with one or more components of the synchronization signal SY. For example, the horizontal synchronization component defines a line frequency. Each of the aforementioned clock signals may be a multiple of the line frequency. This allows the video processor VPR to generate the same integer number of samples for each line of the input video signal of interest, and to process these samples. Moreover, this allows a correct vertical alignment of respective samples on respective lines.

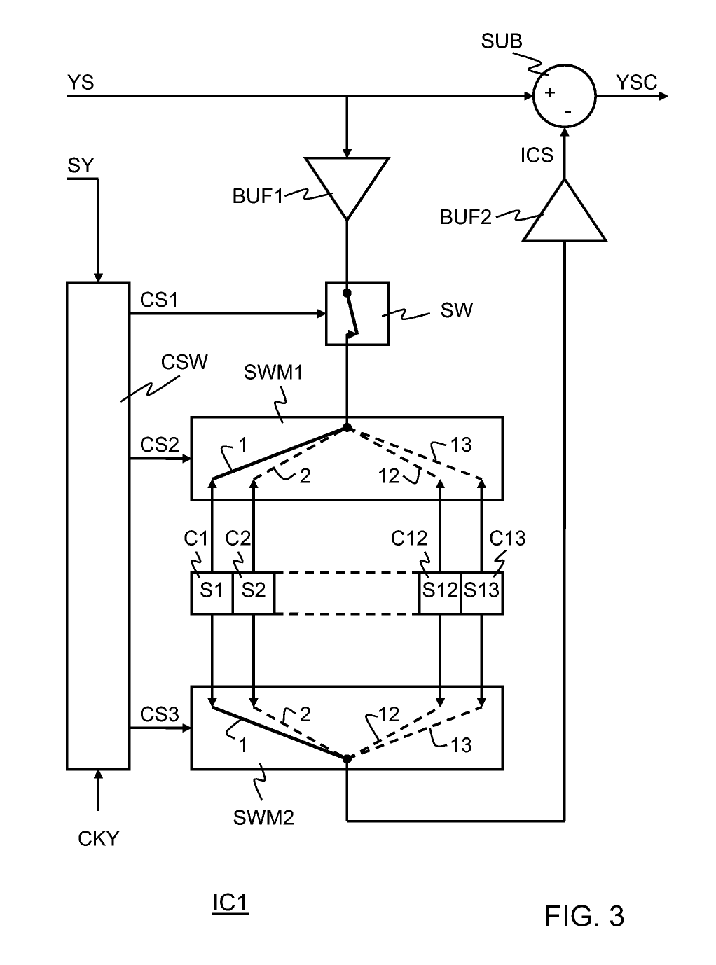

FIG. 3 illustrates interference compensation circuit IC1. Interference compensation circuit IC1 comprises a subtractor SUB, two buffers BUF1, BUF2, a monopole switch SW, two multi-pole switches SWM1, SWM2, an array of memory cells C1-C13, and a switch controller CSW. The monopole switch SW can be switched between an open state and a closed state. Each of the two multi-pole switches SWM1, SWM2 can be switched to any of 13 different positions. In FIG. 3, reference numerals denote these different positions. FIG. 3 illustrates multi-pole switch SWM1 switched to position 1 and multi-pole switch SWM2 equally switched to position 1. The array of memory cells C1-C13 comprises 13 individual memory cells C1, C2, . . . , C12, C13. Each individual memory cell C can store a sample of the stream of analog luminance samples YS, which the interference compensation circuit IC1 receives.

Interference compensation circuit IC1 operates as follows. The synchronization signal SY indicates a blanking interval for a video line. The analog luminance signal YA does not comprise any video information during such a blanking interval. Neither do the respective analog chrominance signals UA, VA. As a result, the stream of analog luminance samples YS will substantially comprise interfering signals during the blanking interval. The aforementioned folding component is one of these interfering signals. In a many applications, the folding component will be by far the most important interfering signal. For that reason, interfering signals other than the folding component will be neglected hereinafter.

The monopole switch SW is in the closed state during at least a portion of the blanking interval. Multi-pole switch SWM1 goes through a switch cycle while the monopole switch SW is in the closed state. A switch cycle corresponds with 13 periods of the luminance clock signal CKY. Multi-pole switch SWM1 has a different position in each of these 13 periods. For example, the multi-pole switch SWM1 has position 1 in a first period of the switch cycle, position 2 in a second period of the switch cycle, and so on, until multi-pole switch SWM1 has position 12 in a 12th period of the switch cycle, and finally position 13 in a 13th period of the switch cycle, which is the last period of the switch cycle.

The stream of analog luminance samples YS comprises a different analog luminance sample for each period of the switch cycle. Accordingly, an analog luminance sample that occurs in the first period of the switch cycle will be stored in memory cell C1. A subsequent analog luminance sample, which occurs in the second period of the switch cycle, will be stored in memory cell C2, and so on. Accordingly, interference compensation circuit IC1 causes 13 successive samples of the stream of analog luminance samples YS to be stored in the array of memory cells C1-C13.

The 13 successive analog luminance samples that are stored in the array of memory cells C1-C13 represent a full period of the folding component. This is because the frequency of the system clock signal CKS, is substantially equal to 12 divided by 13 ( 12/13) times the frequency of the luminance sample clock signal CKY, which is 26.63 MHz. Consequently, the frequency of the folding component is 1/13 of the frequency of the luminance clock signal. As a result, 13 successive periods of the luminance clock signal corresponds with one period of the folding component.

Interference compensation circuit IC1 may cause multi-pole switch SWM1 to go through more than one switch cycle during the blanking interval. The array of memory cells C1-C13 will then comprise an average of different groups of 13 successive analog luminance samples. This allows a more accurate representation of a full period of the folding component. Noise and other sampling errors of random nature are reduced because these are averaged out.

Preferably, the switch controller SWC causes multi-pole switch SWM1 to go through as many switch cycles as a blanking interval allows. For example, a horizontal blanking interval has a length of approximately 10 microseconds (Its). A full period of the folding component lasts approximately 0.5 μs. Consequently, it is possible to establish various different groups of 13 successive analog luminance samples during the horizontal blanking interval. In this respect, it should be noted that a horizontal blanking interval generally comprises a synchronization pulse and a color burst. Preferably, the switch controller SWC prevents multi-pole switch SWM1 from going through a switch cycle when such a pulse or a burst occurs.

Let it now be assumed that the blanking interval has ended. In that case, the stream of analog luminance samples YS comprises video information and, in addition, the folding component. The array of memory cells C1-C13 comprises a sample sequence S1, S2, . . . , S12, S13 that represents a full period of the folding component. Mono-pole switch SW is in the open state.

The switch controller CSW causes multi-pole switch SWM2 to repetitively go through a switch cycle, which corresponds with the switch cycle of multi-pole switch SWM1 described hereinbefore. As a result, buffer BUF2, which reads out the array of memory cells C1-C13 through the multi-pole switch SWM2, will provide a stream of interference compensation samples ICS. The stream of interference compensation samples ICS is a repetitive reproduction of the full period of the folding component, which the sample sequence S1, S2, . . . , S12, S13 in the array of memory cells C1-C13 represents. Stated boldly, the stream of interference compensation samples ICS is a reproduction of the folding component, which was recorded, as it were, during the blanking interval.

The subtractor SUB subtracts the stream of interference compensation samples ICS from the stream of analog luminance samples YS. This cancels out the folding component to relatively large extent. Accordingly, the interference-compensated stream of analog luminance samples YSC is obtained.

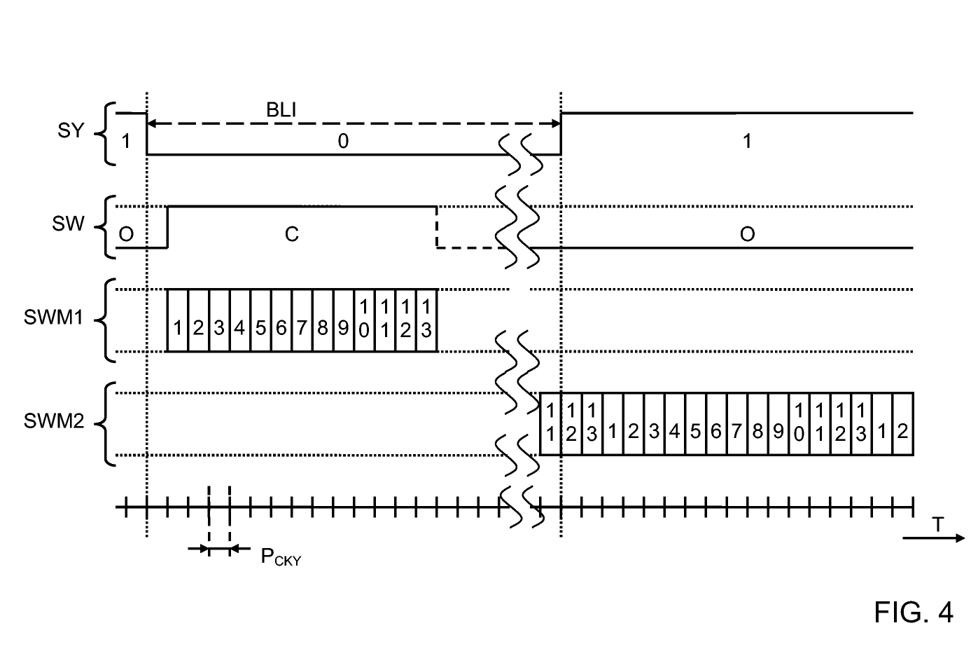

FIG. 4 illustrates operations of interference compensation circuit IC1, which have been described hereinbefore with reference to FIG. 3. FIG. 4 has a time axis T that illustrates respective periods of the luminance sample clock signal CKY. Two successive small vertical lines on the time axis T illustrate a luminance sample clock cycle P_{CKY}. FIG. 4 illustrates the horizontal synchronization component of the synchronization signal SY and respective states of the monopole switch SW, multi-pole switch SWM1, and multi-pole switch SWM2. The horizontal synchronization component of the synchronization signal SY has a first state during a blanking interval BLI and second state outside the blanking interval BLI. Reference numerals 0 and 1 denote the first state and the second state, respectively.

FIG. 4 illustrates that the monopole switch SW is switched from the open state to the closed state shortly after the blanking interval BLI has started. Reference signs O and C denote the open state and the closed state, respectively. For example, the monopole switch SW can be switched from the open state O to the closed state C when the first full luminance sample clock cycle period within the blanking interval BLI starts. FIG. 4 further illustrates that multi-pole switch SWM1 goes through a switch cycle when the monopole switch SW is switched from the open state O to the closed state C. FIG. 4 illustrates the respective positions during the switch cycle by means of reference numerals 1-13, as in FIG. 3. The switch cycle, which FIG. 4 illustrates, may be followed by another switch cycle. Alternatively, the switch cycle may be the only switch cycle during the blanking interval BLI. In that case, the monopole switch SW is switched back from the closed state C to the open state O once the switch cycle has ended. A broken line illustrates this.

FIG. 4 illustrates that multi-pole switch SWM2 has position 12 at the end of the blanking interval BLI, when the horizontal synchronization component goes back from the first state 0 to the second state 1. This position 12 of multi-pole switch SWM2 is merely an example. The position that multi-pole switch SWM2 has at the end of the blanking interval BLI depends on the switch cycle of multi-pole switch SWM1. This is because multi-pole switch SWM2 is synchronized with multi-pole switch SWM1.

The synchronization between multi-pole switch SWM1 and multi-pole switch SWM2 is as follows. Let it be assumed that multi-pole switch SWM2 is continuously made to go through successive switching cycles. As a result, multi-pole switch SWM2 will go through a switching cycle during the blanking interval BLI. In that case, the switching cycle of multi-pole switch SWM2 should preferably correspond with the switching cycle of multi-pole switch SWM1. Accordingly, the stream of interference compensation samples ICS, which FIG. 3 illustrates, will have an appropriate phase so that a satisfactory interference compensation is achieved.

Interference compensation circuits IC2, IC3, which FIG. 2 illustrates, operate in a fashion that is substantially similar to that of interference compensation circuit IC1 described hereinbefore.

Preferably, the following aspect is taken into consideration in order to achieve relatively good interference compensation. The folding component should preferably have similar characteristics during a blanking interval and outside a blanking interval. In that case, the sample sequence S1, S2, . . . , S12, S13 that is stored in the array of memory cells C1-C13 represents the folding component that occurs outside the blanking interval with relatively good precision. The characteristics of the folding component, which is due to a crosstalk of the system clock signal CKS, depend on respective processes that the audio processor APR and the controller CTRL carry out. The audio processor APR and the controller CTRL, which receive the system clock signal CKS, are preferably arranged so that these have approximately the same level of activity during a blanking interval and outside a blanking interval. The level of activity can be expressed in terms of the number of switching elements that change state during successive respective cycles of the system clock signal CKS.

### CONCLUDING REMARKS

The detailed description hereinbefore with reference to the drawings illustrates the following characteristics, which are cited in various independent claims. An input signal (YA), which is processed, comprises a desired signal. The desired signal has a predefined characteristic during an interval of time (BLI). An interference-representing signal (S1-S13) is established on the basis of the input signal (YA) that occurs within the interval of time (BLI) during which the desired signal has the predefined characteristic. The interference-representing signal (S1-S13) represents at least one period of a periodic interfering signal. On the basis of the interference-representing signal (S1-S13), compensation is provided (ICS) for the periodic interfering signal.

The detailed description hereinbefore further illustrates various optional characteristics, which are cited in the dependent claims. These characteristics may be applied to advantage in combination with the aforementioned characteristics. Various optional characteristics are highlighted in the following paragraphs. Each paragraph corresponds with a particular dependent claim.

A sample-and-hold circuit (SH1) takes samples of the input signal (YA). An array of memory cells (C1-C13) stores samples of the input signal (YA) that are taken within the interval of time (BLI) in which the input signal (YA) has the predefined characteristic. These characteristic allows low-cost implementations.

The sample-and-hold circuit (SH1) takes the samples with a sample frequency (26.63 MHz) that is approximately N/M multiplied by the frequency of the periodic interfering signal (24.58 MHz) in the input signal (YA), N and M being integer values. This characteristic further contributes to low-cost implementations because relatively few memory cells are needed to store an accurate estimate of the period of the periodic signal.

The interfering-representing signal is established on the basis of various groups of successive samples of the input signal (YA), which are taken within the interval of time (BLI) in which the input signal (YA) has the predefined characteristic. Each group corresponds with a period of the periodic interfering signal. These characteristics allow relatively precise interference compensation because errors of the random nature are averaged out.

Interference compensation takes place between the sample-and-hold circuit (SH1) and an analog-to-digital converter (ADC). This characteristic allows relatively precise interference compensation at relatively moderate cost. Quantization errors would be introduced if the interference compensator replaced after the analog-to-digital converter.

Interference compensation involves writing of respective samples of the input signal (YA), which are taken within the interval of time (BLI) during which the desired signal has a predefined characteristic, into respective memory cells of the array of memory cells (C1-C13). It further involves reading respective samples of the input signal (YA), which are stored in the array of memory cells (C1-C13), so as to generate an interference compensation signal (ICS). These characteristics allow low-cost implementations.

A processor (CTRL), which receives a clock signal (CKS) that is susceptible to cause the periodic interfering signal through crosstalk, has a substantially similar level of activity within the interval of time (BLI) in which the input signal (YA) has the predefined characteristic and outside that interval of time (BLI). This characteristic contributes to precise interference compensation.

The aforementioned characteristics can be implemented in various different manners. In order to illustrate this, some alternatives are briefly indicated.

The aforementioned characteristics may be applied to advantage in any type of signal processing. Video signal processing is merely an example. The aforementioned characteristics may equally be applied in, for example, signal processing in a cellular phone system, such as, for example, the cellular phone system known under the acronym GSM. All what matters is that a desired signal comprises an interval of time during which the desired signal has a predefined characteristic. Such a predefined characteristic need not necessarily be the absence of any particular information. For example, a predefined bit pattern in, for example, a header within the data stream constitutes a predefined characteristic. All what matters is that there is some form of a priori knowledge of the desired signal.

Interference compensation in accordance with the invention may be carried out at numerous different points in a signal processing chain. The detailed description merely provides an example in which interference compensation takes place between a sample-and-hold circuit and an analog-to-digital converter. As another example, interference compensation can also take place after the analog-to-digital converter. In such an implementation, digital samples are collected within the blanking interval so as to form a digital representation of a period of the folding component. This digital representation can then be used for compensating the folding component outside the blanking interval. It is also possible to place an interference compensator before the sample-and-hold circuit. In that case, a residue of the system clock signal will constitute the interfering signal that needs to be compensated. However, such an alternative will generally be less effective because a further residue may be introduced between the interference compensator and the sample-and-hold circuit. Furthermore, such an alternative will generally be more expensive because the interfering signal, which needs to be compensated, has a relatively high frequency.

There are numerous different manners to carry out interference compensation in accordance with the invention. FIGS. 3 and 4 merely illustrate an example that involves a writing of samples into an array of memory cells and, subsequently, a cyclic reading of the samples that have been stored in the array of memory cells. Interference compensation in accordance with the invention may involve more sophisticated and more complex signal handling. For example, input signal samples that are collected within the interval of time during which the desired signal has the predefined characteristic, may be subject to extrapolation and interpolations operations. This allows an accurate estimate of a period of the periodic interfering signal for any arbitrary frequency that the signal may have. An interference compensator in accordance with the invention may comprise any hardware or software, or both, that carry out sophisticated signal analysis to accurately estimate the periodic interfering signal and to reconstruct that signal.

There are several ways of implementing functions by means of items of hardware or software, or both. In this respect, the drawings are diagrammatic, each representing only one possible embodiment of the invention. Thus, although a drawing shows different functions as different blocks, this by no means excludes that a single item of hardware or software carries out several functions. Nor does it exclude that an assembly of items of hardware or software or both carry out a function.

The remarks made herein before demonstrate that the detailed description with reference to the drawings, illustrate rather than limit the invention. There are several alternatives that fall within the scope of the appended claims. Any reference sign in a claim should not be construed as limiting the claim. The word “comprising” does not exclude the presence of other elements or steps than those listed in a claim. The word “a” or “an” preceding an element or step does not exclude the presence of a plurality of such elements or steps.

1. A signal processing arrangement for reducing periodic interference signal components in an input signal to obtain a desired signal, the signal processing arrangement comprising:
a first circuit for storing an interference-representing signal representing at least one period of a periodic interfering signal on the basis of the input signal during an interval of time during which the desired signal has a predefined characteristic, and
a second circuit for repetitively providing, on the basis of the interference-representing, compensation for the periodic interfering signal.

2. A signal processing arrangement according to claim 1, the first circuit comprising:
a sample-and-hold circuit for taking samples of the input signal; and
an array of memory cells for storing samples of the input signal that are taken within the interval of time in which the input signal has the predefined characteristic.

3. A signal processing arrangement according to claim 2, the sample-and-hold circuit being arranged to take the samples with a sample frequency that is approximately N/M multiplied by the frequency of a periodic interfering signal in the input signal, N and M being integer values.

4. A signal processing arrangement according to claim 2, the first circuit being arranged to establish the interference-representing signal on the basis of various groups of successive samples of the input signal, which are taken within the interval of time in which the input signal has the predefined characteristic, each group corresponding with a period of the periodic interfering signal.

5. A signal processing arrangement according to claim 2, wherein the first circuit comprises a writing arrangement for writing into respective memory cells of the array of memory cell respective samples of the input signalize, which are taken within the interval of time during which the desired signal has a predefined characteristic; and
the second circuit comprises a reading arrangement for cyclically reading the respective samples of the input, which are stored in the array of memory cells, so as to generate an interference compensation signal.

6. A signal processing arrangement according to claim 1, the signal processing arrangement comprising:
a processor coupled to receive a clock signal which is susceptible to cause the periodic interfering signal through crosstalk, the processor being arranged to have a substantially similar level of activity within the interval of time in which the input signal has the predefined characteristic and outside that interval of time.

7. A method of reducing periodic interference signal components in an input signal to obtain a desired signal, the method comprising:
an interference determining step in which an interference-representing signal representing at least one period of a periodic interfering signal is stored on the basis of the input signal during an interval of time during which the desired signal has a predefined characteristic; and
an interference compensation step in which, on the basis of the interference-representing signal, compensation is repetitively provided for the periodic interfering signal.

8. A computer program product that comprises a set of instructions, which when loaded into a signal processing arrangement, enables the signal processing arrangement to carry out the method according to claim 7.

9. An information-rendering system comprising a signal processing arrangement according to claim 1, and an information-rendering device for rendering an output signal that the signal processing arrangement provides.
